(19) United States
(12) Patent Application Publication
(10) Pub. No.: US 2005/0048712 A1
(43) Pub. Date: Mar. 3, 2005

(54) Method for forming high voltage complementary metal-oxide semiconductor by utilizing retrograde ion implantation

(76) Inventor: Jung-Cheng Kao, Shanghai (CN)

Correspondence Address: ROSENBERG, KLEIN & LEE, 3458 ELLICOTT CENTER DRIVE-SUITE 101, ELLICOTT CITY, MD, 21043, US

(21) Appl. No.: 10/922,857

(22) Filed: Aug. 23, 2004

(30) Foreign Application Priority Data
Aug. 27, 2003 (CN) 03150607.0

(51) Int. Cl. H01L 21/8238; H01L 21/425

(52) U.S. Cl. 438/228; 438/227; 438/225; 438/199; 438/229; 438/527

(57) ABSTRACT

A method for forming a high voltage complementary metal-oxide semiconductor (high voltage CMOS) by utilizing a retrograde ion implantation step. The present invention utilizes a retrograde ion implantation step on a dopant well area, the N-drift region and the N-drift region of the high voltage CMOS structure. After forming the field oxide isolation structure, the present invention utilizes the high voltage ion implantation step to form these dopant areas. The high voltage CMOS structure formed in the present invention is provided with better electronic characteristics. In the present invention, the anti breakdown voltage is higher and the driving current is also larger. The present invention can also shrink the area of the whole devices.

### BACKGROUND OF THE INVENTION

1. Field of the Invention

The present invention generally relates to a processing method of a high voltage device, and more particularly relates to a method for forming a high voltage complementary metal-oxide semiconductor (high voltage CMOS) by utilizing a retrograde ion implantation step.

2. Description of the Prior Art

High voltage devices are applied to components that require high voltage operation in electronic products. Usually, in the architecture of integrated circuits, the control device of the I/O region of some products requires higher voltages than the control device of the key device region. Therefore, the I/O region must be provided with devices that have a higher ability to bear high voltages so as not to cause breakdown effects under normal high voltage operation. Hence, the structure of the high voltage device is not similar to normal devices.

Referring to the FIG. 1, which illustrates the structure of a high voltage complementary metal-oxide semiconductor (high voltage CMOS) in accordance with conventional technology. There is an N-well 12 formed in a P type semiconductor substrate 10. Then, an N-drift region 14 is formed in the NMOS region and a P-drift region 16 is formed in the PMOS region. Following, a field oxide layer 18, a gate oxide layer 20, and a polysilicon gate 22 are formed on the semiconductor substrate 10. Last, an ion implantation step is performed to form an N+ type dopant area 24 in the NMOS region and a P+ type dopant area 26 in the PMOS region in the semiconductor substrate 10 to be respectively use as a source and a drain.

In the prior processing method mentioned above, in the region near the A point of the FIG. 1, where the formed N-drift region 14 is through the channel surface, the density of the electric field is higher, so the depletion region formed by the N-drift region 14 can not resist the electric field of high voltage and therefore it break downs easily. In order to enhance the breakdown voltage, the traditional method reduces the dopant concentration of the N-drift region 14 so as to increase the width of the depletion region to achieve the purpose of increasing the breakdown voltage. However, when the dopant concentration of the N-drift region 14 is reduced, it will increase the resistance of the channel at this region and its on-resistance will be increased to cause the decreasing of the current driving ability of the transistor device.

Obviously, in accordance with the problems mentioned above, the present invention provides a method for forming a high voltage complementary metal-oxide semiconductor (high voltage CMOS) by utilizing a retrograde ion implantation step which overcomes the disadvantages of conventional technology.

### SUMMARY OF THE INVENTION

The present invention provides a method for forming a high voltage complementary metal-oxide semiconductor (high voltage CMOS) by utilizing a retrograde ion implantation step. In the present invention, the high voltage CMOS is provided with better electronic ability, wherein the anti breakdown voltage is higher and the current driving ability becomes larger.

In the present invention, the design rule of the high voltage CMOS can be greatly shrunken so as to effectively shrink the area of the whole device.

The present invention also provides a processing method for a high voltage complementary metal-oxide semiconductor (high voltage CMOS), which can improve the generation of the latch-up effect.

In order to achieve previous objects, the present invention forms an isolation structure and a sacrificial oxide layer on a semiconductor substrate. Then, a retrograde ion implantation step is utilized to form a heavily doped well area, a lightly doped N-drift region and a lightly doped P-drift region by a high voltage ion implantation step. Following, a thermal process is performed to drive in those dopants into the semiconductor substrate and then the sacrificial oxide layer is removed. Next, a gate oxide layer is formed on the semiconductor substrate and a photolithography and etching process is utilized to form a gate oxide layer and a polysilicon gate structure on the semiconductor substrate. An ion implantation step is performed on the semiconductor substrate at both sides of the polysilicon gate structure, wherein a heavily N type dopant area and a heavily P type dopant area are respectively formed in the N-drift region and the P-drift region so as to be used as a source/drain.

Other advantages of the present invention will become apparent from the following description taken in conjunction with the accompanying drawings wherein are set forth, by way of illustration and example, certain embodiments of the present invention.

### BRIEF DESCRIPTION OF THE DRAWINGS

The foregoing aspects and many of the accompanying advantages of this invention will become more readily appreciated as the same becomes better understood by reference to the following detailed description, when taken in conjunction with the accompanying drawings, wherein:

FIG. 1 is a schematic representation of the cross section of a high voltage complementary metal-oxide semiconductor (high voltage CMOS) in accordance with conventional technology; and

FIG. 2a, FIG. 2b, FIG. 2c, and FIG. 2d are schematic representations of the cross section of the various steps of the formulation of the high voltage complementary metal-oxide semiconductor (high voltage CMOS) in accordance with an embodiment of the present invention.

### DESCRIPTION OF THE PREFERRED EMBODIMENT

The present invention utilizes a retrograde ion implantation step to form a heavily doped area, a lightly doped N-drift region, and a lightly doped P-drift region in the semiconductor substrate with an isolation structure by using the high voltage ion implantation step. The lightly doped N-drift region and the lightly doped P-drift region are respectively for being used as the NMOS region and PMOS region of the high voltage complementary metal-oxide semiconductor (high voltage CMOS). Hence, the high voltage CMOS of the present invention is provided with better electronic characteristics so as to overcome the disadvantages of the prior technology.

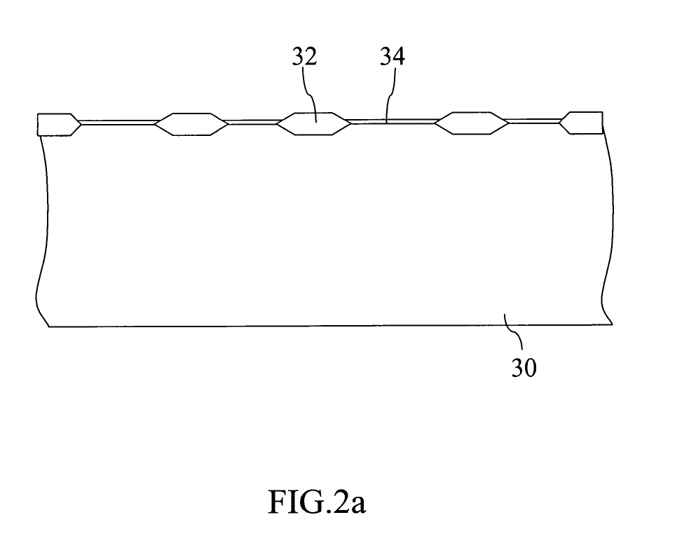

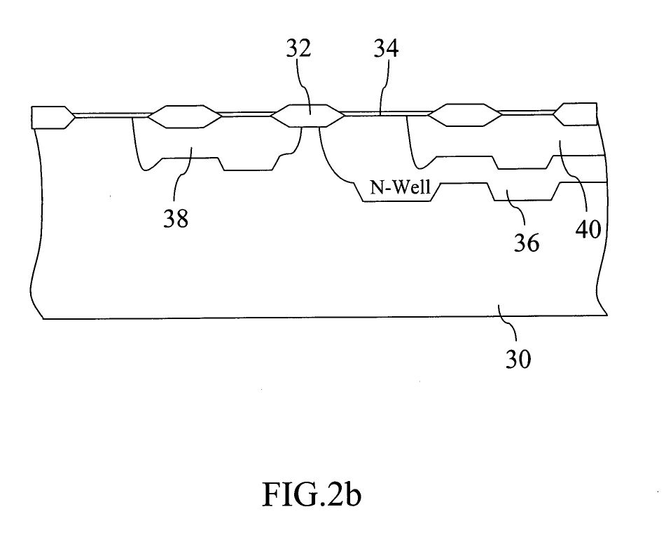

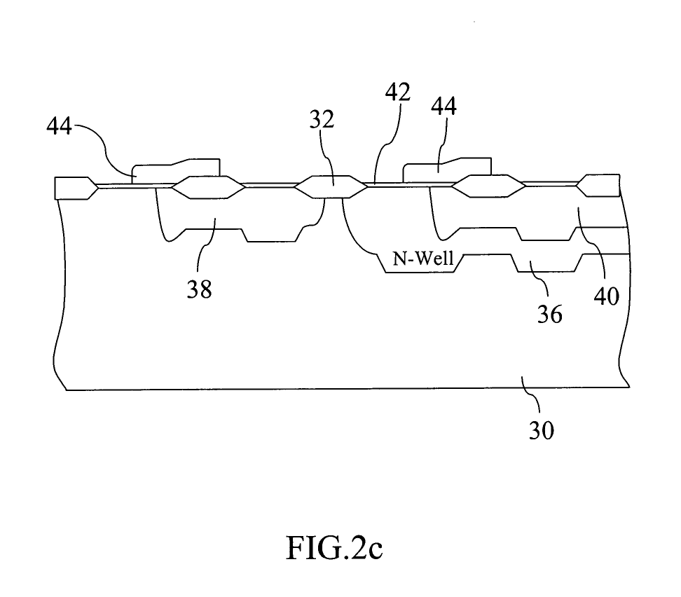

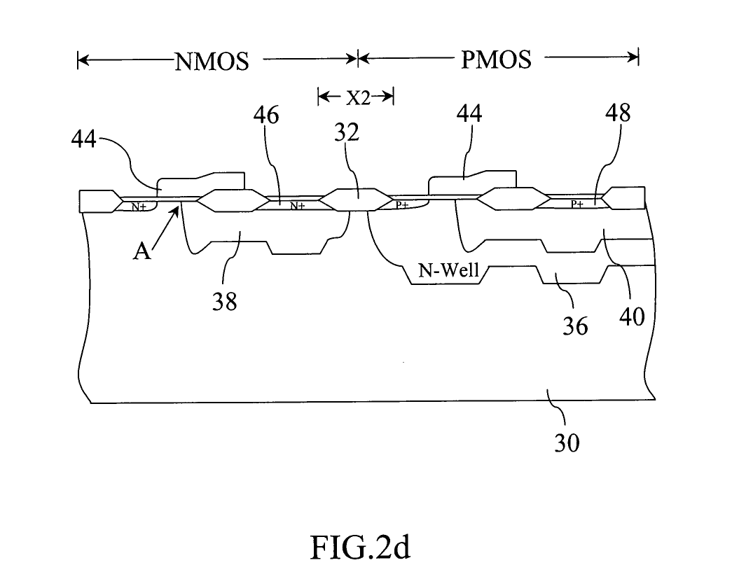

Refer to FIG. 2a, FIG. 2b, FIG. 2c, and FIG. 2d which are schematic representations of the cross section of the various steps of the formulation of the high voltage complementary metal-oxide semiconductor (high voltage CMOS) in accordance with an embodiment of the present invention. As shown in the Figures, the present invention comprising the following steps. First, referring to FIG. 2a a semiconductor substrate 30 is provided and a chemical vapor deposition technology is utilized to sequentially form a thin oxide layer, an oxide layer, and a patterned silicon nitride layer on the surface of the semiconductor substrate 30. The thin oxide layer, the oxide layer, and the patterned silicon nitride layer are not shown in the figures. The patterned silicon nitride layer is used as a mask to etch the oxide layer so as to form a field oxide isolation structure 32, such as shown in FIG. 2a. Next, an etching step is performed to remove the silicon nitride layer and the thin oxide layer and then a sacrificial oxide layer 34 is grown as shown in the figure.

Following, referring to FIG. 2b, the heavily doped N-well region 36 is formed by utilizing a retrograde ion implantation with an energy of about 400 to 800 KeV to implant a N type dopant of the phosphorous ion with a concentration of about 5*10¹² to 1*10¹⁴ per cm² into the semiconductor substrate 30. The lightly doped N-drift region 38 is formed by utilizing a retrograde ion implantation with an energy of about 200 to 600 KeV to implant a N type dopant of phosphorous ions or arsenic ions with a concentration of about 5* 10¹² to 1*10¹⁴ per cm² into the semiconductor substrate 30. Then, a lightly doped P-drift region 40 is formed by utilizing an retrograde ion implantation with an energy of about 100 to 300 KeV to implant a P type dopant of Boron ions with a concentration of about 1*10¹³ to 1*10¹⁴ per cm² into the semiconductor substrate 30.

Then, after a thermal process, the dopant ions are driven in the semiconductor substrate 30. This drive in step is utilized to adjust the concentration distribution and to repair the lattice structure at the ion-striking region. Next, an etching step is performed to remove the sacrificial layer 34.

Referring to FIG. 2c, first, a gate oxide layer 42 is grown on the surface of the semiconductor substrate 30. Then, a polysilicon layer is deposited on the gate oxide layer. A photolithography and etching process are performed to respectively form a polysilicon gate structure 44 on a lightly doped N-drift region 38 and a lightly doped P-drift region 40.

An ion implantation step is performed on the semiconductor substrate 30 to both sides of the polysilicon gate structure 44, wherein a heavily N type dopant area 46 and a heavily P type dopant area 48 are respectively formed in the N-drift region 38 and the P-drift region 40, such as shown in the FIG. 2d. The heavily N type dopant area 46 is used as the source/drain of the N-drift region 38 to form the NMOS structure and the heavily P type dopant area 48 which is used as the source/drain of the P-drift region 40 to form the PMOS structure.

Following, the high voltage complementary metal-oxide semiconductor (high voltage CMOS) structure of the present invention is as shown in the FIG. 2d. The channel under the field oxide isolation structure 32 is the high concentration point of the N-drift region 38 and the P-drift region 40 and the concentration near the A point position is the lowest concentration. Since the concentration of the channel under the field oxide isolation structure 32 is much larger than the conventional technology and the concentration near the A point position has a much lower concentration than the prior technology the breakdown voltage of the high voltage CMOS of the present invention is higher and the current driving characteristics are much improved.

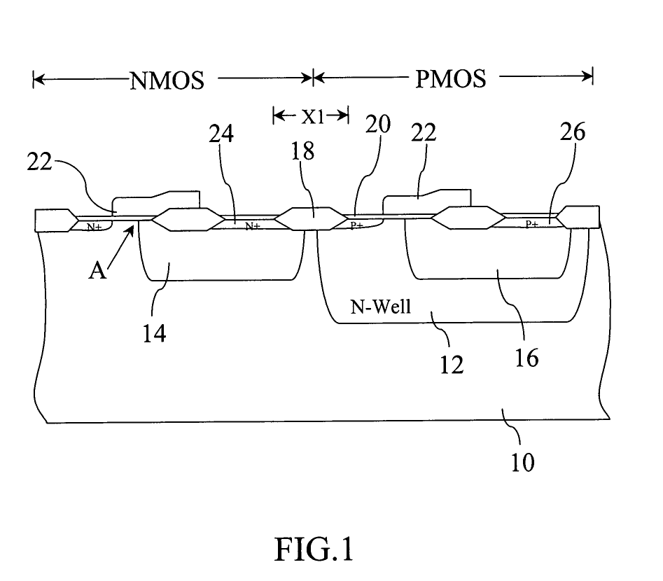

Additionally, the design rule of the high voltage complementary metal-oxide semiconductor (high voltage CMOS) of the present invention can be greatly shrunken. Take the field oxide isolation structure isolating the NMOS and the PMOS for an example, the X2 shown in FIG. 2d is about 5 μm which is much smaller than the prior technology, where the X1 is about 15 μm as shown in FIG. 1. Hence, the present invention can effectively shrink the area of the whole device. Further, the present invention can also improve the problem of generation of the latch-up effect.

The forgoing description of the embodiments of the invention has been presented for purposes of illustration and description, and is not intended to be exhaustive or to limit the present invention to he precise from disclosed. The description was selected to best explain the principles of the invention and practical application of these principles to enable others skilled in the art to best utilize the invention in various embodiments and modifications as are suited to the particular use contemplated. It is intended that the scope of the invention not to be limited by the specification, but be defined by the claim set forth below.

1. A method for forming a high voltage complementary metal-oxide semiconductor by utilizing a retrograde ion implantation step, the method comprising:
providing a semiconductor substrate, wherein an isolation structure and a sacrificial oxide layer are formed on the semiconductor substrate;
utilizing a retrograde ion implantation step to form a heavily doped well area, a lightly doped N-drift region and a lightly doped P-drift region;
performing a thermal process to drive in the dopants into the semiconductor substrate and then removing the sacrificial oxide layer;
forming a gate oxide layer on the semiconductor substrate and utilizing a photolithography and etching process to form a polysilicon gate structure; and
performing an ion implantation step in the semiconductor substrate at both sides of the polysilicon gate structure, wherein a heavily N type dopant area and a heavily P type dopant area are respectively formed in the N-drift region and in the P-drift region so as to be used as a source/drain.

2. The method for forming a high voltage complementary metal-oxide semiconductor according to claim 1, wherein the semiconductor substrate is made of a P type semiconductor substrate and the heavily doped well area is an N type dopant well area.

3. The method for forming a high voltage complementary metal-oxide semiconductor according to claim 1, wherein the isolation structure is a field oxide isolation structure.

4. The method for forming a high voltage complementary metal-oxide semiconductor according to claim 3, wherein the field oxide isolation structure is formed by utilizing a patterned silicon nitride layer as a mask and etching an oxide layer.

5. The method for forming a high voltage complementary metal-oxide semiconductor according to claim 1, wherein the heavily doped area is formed by utilizing an energy of about 400 to 800 KeV to implant a dopant with a concentration of about 5*10¹² to 1*10¹⁴ per cm² into the semiconductor substrate.

6. The method for forming a high voltage complementary metal-oxide semiconductor according to claim 5, wherein said dopant ion is an N type dopant ion and the preferred dopant is a phosphorous ion.

7. The method for forming a high voltage complementary metal-oxide semiconductor according to claim 1, wherein the heavily doped area is formed by utilizing an energy of about 200 to 600 KeV to implant a N type dopant ion with a concentration of about 5*10¹² to 1*10¹⁴ per cm² into the semiconductor substrate.

8. The method for forming a high voltage complementary metal-oxide semiconductor according to claim 7, wherein the N type dopant ion comprised phosphorous ion and arsenic ion.

9. The method for forming a high voltage complementary metal-oxide semiconductor according to claim 1, wherein the heavily doped area is formed by utilizing an energy of about 100 to 300 KeV to implant a P type dopant ion with a concentration of about 1*10¹³ to 1*10¹⁴ per cm² into the semiconductor substrate.

10. The method for forming a high voltage complementary metal-oxide semiconductor according to claim 9, wherein the P type dopant ion is a Boron ion.
